(19) United States
(12) Patent Application Publication
(10) Pub. No.: US 2020/0377713 A1
(43) Pub. Date: Dec. 3, 2020

(54) POLYMERS, PHOTORESIST COMPOSITIONS AND PATTERN FORMATION METHODS

(71) Applicant: ROHM AND HAAS ELECTRONIC MATERIALS LLC, Marlborough, MA (US)

(72) Inventors: Joshua Kaitz, Watertown, MA (US); Xisen Hou, Lebanon, NH (US); Mingqi Li, Shrewsbury, MA (US); Tomas Marangoni, Marlborough, MA (US); Emad Aqad, Northborough, MA (US); Yang Song, Framingham, MA (US)

(21) Appl. No.: 16/885,628

(22) Filed: May 28, 2020

Related U.S. Application Data
(60) Provisional application No. 62/855,689, filed on May 31, 2019.

(51) Int. Cl. C08L 33/24; G03F 7/004; G03F 7/20; C08L 33/06; C08L 33/14

(52) U.S. Cl. CPC C08L 33/24; G03F 7/0045; C08L 33/14; C08L 33/066; G03F 7/2004

(57) ABSTRACT

Disclosed herein is a polymer comprising a first repeat unit and a second repeat unit, where the first repeat unit contains an acid labile group and where the second repeat unit has the structure of formula (1):

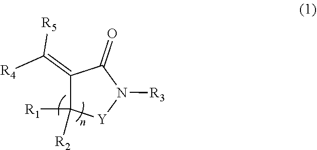

wherein R₁, R₂ and R₃ are each independently hydrogen, a halogen, a substituted or unsubstituted C₁ to C₁₂ alkyl group or C₃ to C₁₂ cycloalkyl group optionally containing an ether group, a carbonyl group, an ester group, a carbonate group, an amine group, an amide group, a urea group, a sulfate group, a sulfone group, a sulfoxide group, an N-oxide group, a sulfonate group, a sulfonamide group, or a combination thereof, a substituted or unsubstituted C₆ to C₁₄ aryl group, or C₃ to C₁₂ heteroaryl group, wherein the substitution is halogen, hydroxyl, cyano, nitro, C₁ to C₁₂ alkyl group, C₁ to C₁₂ haloalkyl group, C₁ to C₁₂ alkoxy group, C₃ to C₁₂ cycloalkyl group, amino, C₂-C₆ alkanoyl, carboxamido, a substituted or unsubstituted C₆ to C₁₄ aryl group, or C₃ to C₁₂ heteroaryl group; wherein R₁ and R₂ together optionally form a ring; and wherein n=1-3.

### CROSS REFERENCE TO RELATED APPLICATIONS

This application claims the benefit of U.S. Provisional Application Ser. No. 62/855,689, filed May 31, 2019, the disclosure of which is incorporated herein by reference in its entirety.

### BACKGROUND

This disclosure relates to polymers that can be used in resist compositions, methods of manufacture thereof and to articles containing the same. In particular, this disclosure relates to polymers used in resist compositions that comprise lactams and cyclic imides, methods of manufacture thereof and to articles containing the same.

State-of-the-art lithographic patterning processes currently employ ArF (193 nm) immersion scanners to process wafers at dimensions that are less than 60 nanometers (nm). Pushing ArF lithography to sub-60 nm critical dimensions creates several challenges for the photoresist capabilities in terms of process window, line width roughness (LWR), and other critical parameters for high volume manufacturing of integrated circuits. All of these parameters must be addressed in next-generation formulations. As pattern dimensions are reduced in advanced nodes, LWR values have not been concurrently reduced at the same rate, creating a significant source of variation during processing at those leading-edge nodes. Process window improvements are also useful for achieving high yield in integrated circuit manufacturing.

It is therefore desirable to manufacture photoresist compositions that display improved LWR performance, provide a more robust process window and have better solubility in process solvents.

### SUMMARY

Disclosed herein is a polymer comprising a first repeat unit and a second repeat unit, where the first repeat unit contains an acid labile group and where the second repeat unit has the structure of formula (1):

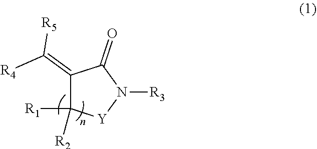

wherein R₁, R₂ and R₃ are each independently hydrogen, a halogen, a substituted or unsubstituted C₁ to C₁₂ alkyl group or C₃ to C₁₂ cycloalkyl group optionally containing an ether group, a carbonyl group, an ester group, a carbonate group, an amine group, an amide group, a urea group, a sulfate group, a sulfone group, a sulfoxide group, an N-oxide group, a sulfonate group, a sulfonamide group, or a combination thereof, a substituted or unsubstituted C₆ to C₁₄ aryl group, or C₃ to C₁₂ heteroaryl group, wherein the substitution is halogen, hydroxyl, cyano, nitro, C₁ to C₁₂ alkyl group, C₁ to C₁₂ haloalkyl group, C₁ to C₁₂ alkoxy group, C₃ to C₁₂ cycloalkyl group, amino, C₂-C₆ alkanoyl, carboxamido, a substituted or unsubstituted C₆ to C₁₄ aryl group, or C₃ to C₁₂ heteroaryl group; wherein R₁ and R₂ together optionally form a ring; wherein Y is chosen from carbonyl, sulfonyl, or substituted or unsubstituted methylene, wherein Y and R₂ together optionally form a substituted or unsubstituted 4-7 member monocyclic ring or a substituted or unsubstituted 9-12 member bicyclic ring, the monocyclic and bicyclic rings optionally containing 1, 2, or 3 heteroatoms chosen from N, O, and S, wherein each ring is saturated, unsaturated, or aromatic, and wherein each ring optionally contains an ether group, a carbonyl group, an ester group, a carbonate group, an amine group, an amide group, a urea group, a sulfate group, a sulfone group, a sulfoxide group, an N-oxide group, a sulfonate group, a sulfonamide group, or a combination thereof, wherein the substitution on the ring is halogen, hydroxyl, cyano, nitro, C₁ to C₁₂ alkyl group, C₁ to C₁₂ haloalkyl group, C₁ to C₁₂ alkoxy group, C₃ to C₁₂ cycloalkyl group, amino, C₂-C₆ alkanoyl, carboxamido, a substituted or unsubstituted C₆ to C₁₄ aryl group, or C₃ to C₁₂ heteroaryl group; and wherein R₄ and R₅ are each independently hydrogen, halogen, a substituted or unsubstituted C₁ to C₃ alkyl group where the substitution is halogen; and wherein n=1-3.

### DETAILED DESCRIPTION

### Definitions

In this disclosure, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation.

The argon fluoride laser (ArF laser) is a particular type of excimer laser, which is sometimes referred to as an exciplex laser. “Excimer” is short for “excited dimer”, while “exciplex” is short for “excited complex”. An excimer laser uses a mixture of a noble gas (argon, krypton, or xenon) and a halogen gas (fluorine or chlorine), which under suitable conditions of electrical stimulation and high pressure, emits coherent stimulated radiation (laser light) in the ultraviolet range.

Furthermore, “exposure” in the present specification includes, unless otherwise specified, not only exposure by a mercury lamp, far ultraviolet rays represented by an excimer laser, X-rays, extreme ultraviolet rays (EUV light), or the like, but also writing by particle rays such as electron beams and ion beams.

In the present specification, “(a value) to (a value)” means a range including the numerical values described before and after “to” as a lower limit value and an upper limit value, respectively.

A dash (“-”) that is not between two letters or symbols is used to indicate a point of attachment for a substituent. For example, —(CH₂)C₃-C₅ cycloalkyl is attached through carbon of the methylene (CH₂) group.

In the present specification, “(meth)acrylate” represents “at least one of acrylate and methacrylate.” In addition, “(meth)acrylic acid” means “at least one of acrylic acid and methacrylic acid”.

“Alkanoyl” is an alkyl group as defined herein, covalently bound to the group it substitutes by a keto (—(C═O)—) bridge. Alkanoyl groups have the indicated number of carbon atoms, with the carbon of the keto group being included in the numbered carbon atoms. For example a C₂ alkanoyl group is an acetyl group having the formula CH₃(C═O)—.

The term “alkyl”, as used herein, means a branched or straight chain saturated aliphatic hydrocarbon group having the specified number of carbon atoms, generally from 1 to about 12 carbon atoms. The term C₁-C₆ alkyl as used herein indicates an alkyl group having from 1, 2, 3, 4, 5, or 6 carbon atoms. Other embodiments include alkyl groups having from 1 to 8 carbon atoms, 1 to 4 carbon atoms or 1 or 2 carbon atoms, e.g. C₁-C₆ alkyl, C₁-C₄ alkyl, and C₁-C₂ alkyl. When C₀-Cₙ alkyl is used herein in conjunction with another group, for example, (cycloalkyl)C₀-C₄ alkyl, the indicated group, in this case cycloalkyl, is either directly bound by a single covalent bond (C₀), or attached by an alkyl chain having the specified number of carbon atoms, in this case 1, 2, 3, or 4 carbon atoms. Examples of alkyl include, but are not limited to, methyl, ethyl, n-propyl, isopropyl, n-butyl, 3-methylbutyl, t-butyl, n-pentyl, and sec-pentyl.

The term “cycloalkyl”, as used herein, indicates a saturated hydrocarbon ring group, having only carbon ring atoms and having the specified number of carbon atoms, usually from 3 to about 8 ring carbon atoms, or from 3 to about 7 carbon atoms. Examples of cycloalkyl groups include cyclopropyl, cyclobutyl, cyclopentyl, or cyclohexyl as well as bridged or caged saturated ring groups such as norborane or adamantane.

The term “heterocycloalkyl”, as used herein, indicates a saturated cyclic group containing from 1 to about 3 heteroatoms chosen from N, O, and S, with remaining ring atoms being carbon. Heterocycloalkyl groups have from 3 to about 8 ring atoms, and more typically have from 5 to 7 ring atoms. Examples of heterocycloalkyl groups include morpholinyl, piperazinyl, piperidinyl, and pyrrolidinyl groups. A nitrogen in a heterocycloalkyl group may optionally be quaternized.

In citations for a group and an atomic group in the present specification, in a case where the group is denoted without specifying whether it is substituted or unsubstituted, the group includes both a group and an atomic group not having a substituent, and a group and an atomic group having a substituent. For example, an “alkyl group” which is not denoted about whether it is substituted or unsubstituted includes not only an alkyl group not having a substituent (unsubstituted alkyl group), but also an alkyl group having a substituent (substituted alkyl group).

The term “alkenyl”, as used herein, means straight and branched hydrocarbon chains comprising one or more unsaturated carbon-carbon bonds, which may occur in any stable point along the chain. Alkenyl groups described herein typically have from 2 to about 12 carbon atoms. Exemplary alkenyl groups are lower alkenyl groups, those alkenyl groups having from 2 to about 8 carbon atoms, e.g. C2-C8, C2-C6, and C2-C4 alkenyl groups. Examples of alkenyl groups include ethenyl, propenyl, and butenyl groups.

The term “alkynyl”, means straight and branched hydrocarbon chains comprising one or more C≡C carbon-carbon triple bonds, which may occur in any stable point along the chain. Alkynyl groups described herein typically have from 2 to about 12 carbon atoms. Exemplary alkynyl groups are lower alkynyl groups, those alkenyl groups having from 2 to about 8 carbon atoms, e.g. C2-C8, C2-C6, and C2-C4 alkynyl groups. Examples of alkynyl groups include ethynyl, propynyl, and butynyl groups.

The term “cycloalkenyl”, as used herein, means a saturated hydrocarbon ring group, comprising one or more unsaturated carbon-carbon bonds, which may occur in any stable point of the ring, and having the specified number of carbon atoms. Monocyclic cycloalkenyl groups typically have from 3 to about 8 carbon ring atoms or from 3 to 7 (3, 4, 5, 6, or 7) carbon ring atoms. Cycloalkenyl substituents may be pendant from a substituted nitrogen or carbon atom, or a substituted carbon atom that may have two substituents may have a cycloalkenyl group, which is attached as a spiro group. Examples of cycloalkenyl groups include cyclopropenyl, cyclobutenyl, cyclopentenyl, or cyclohexenyl as well as bridged or caged saturated ring groups such as norbornene.

The terms “(cycloalkyl)C0-Cn alkyl”, as used herein, means a substituent in which the cycloalkyl and alkyl are as defined herein, and the point of attachment of the (cycloalkyl)alkyl group to the molecule it substitutes is either a single covalent bond, (C0alkyl) or on the alkyl group. (Cycloalkyl)alkyl encompasses, but is not limited to, cyclopropylmethyl, cyclobutylmethyl, and cyclohexylmethyl.

The terms “(heterocycloalkyl)C0-Cn alkyl”, as used herein, means a substituent in which the heterocycloalkyl and alkyl are as defined herein, and the point of attachment of the (heterocycloalkyl)alkyl group to the molecule it substitutes is either a single covalent bond, (C0 alkyl) or on the alkyl group. (Heterocycloalkyl)alkyl encompasses, but is not limited to, morpholinylmethyl, piperazinylmethyl, piperidinylmethyl, and pyrrolidinylmethyl groups.

The term “aryl”, as used herein, means aromatic groups containing only carbon in the aromatic ring or rings. Typical aryl groups contain 1 to 3 separate, fused, or pendant rings and from 6 to about 18 ring atoms, without heteroatoms as ring members. When indicated, such aryl groups may be further substituted with carbon or non-carbon atoms or groups. Bicyclic aryl groups may be further substituted with carbon or non-carbon atoms or groups. Bicyclic aryl groups may contain two fused aromatic rings (naphthyl) or an aromatic ring fused to a 5- to 7-membered non-aromatic cyclic group that optionally contains 1 or 2 heteroatoms independently chosen from N, O, and S, for example, a 3,4-methylenedioxy-phenyl group. Aryl groups include, for example, phenyl, naphthyl, including 1-naphthyl and 2-naphthyl, and bi-phenyl.

The term “mono- or bicyclic heteroaryl”, as used herein, indicates a stable 5- to 7-membered monocyclic or 7- to 10-membered bicyclic heterocyclic ring which contains at least 1 aromatic ring that contains from 1 to 4, or specifically from 1 to 3, heteroatoms chosen from N, O, and S, with remaining ring atoms being carbon. When the total number of S and O atoms in the heteroaryl group exceeds 1, theses heteroatoms are not adjacent to one another. Specifically, the total number of S and O atoms in the heteroaryl group is not more than 2, more specifically the total number of S and O atoms in the heteroaryl group is not more than 1. A nitrogen atom in a heteroaryl group may optionally be quaternized. When indicated, such heteroaryl groups may be further substituted with carbon or non-carbon atoms or groups. Such substitution may include fusion to a 5 to 7-membered saturated cyclic group that optionally contains 1 or 2 heteroatoms independently chosen from N, O, and S, to form, for example, a [1,3]dioxolo[4,5-c]pyridyl group. In certain embodiments 5- to 6-membered heteroaryl groups are used. Examples of heteroaryl groups include, but are not limited to, pyridyl, indolyl, pyrimidinyl, pyridizinyl, pyrazinyl, imidazolyl, oxazolyl, furanyl, thiophenyl, thiazolyl, triazolyl, tetrazolyl, isoxazolyl, quinolinyl, pyrrolyl, pyrazolyl, benz[b]thiophenyl, isoquinolinyl, quinazolinyl, quinoxalinyl, thienyl, isoindolyl, and 5,6,7,8-tetrahydroisoquinoline.

“Haloalkyl” includes both branched and straight-chain alkyl groups having the specified number of carbon atoms, substituted with 1 or more halogen atoms, up to the maximum allowable number of halogen atoms. Examples of haloalkyl include, but are not limited to, trifluoromethyl, difluoromethyl, 2-fluoroethyl, and penta-fluoroethyl.

“Haloalkoxy” is a haloalkyl group as defined herein attached through an oxygen bridge (oxygen of an alcohol radical).

“Halo” or “halogen” is any of fluoro, chloro, bromo, and iodo.

“Mono- and/or di-alkylamino” is a secondary or tertiary alkyl amino group, wherein the alkyl groups are independently chosen alkyl groups, as defined herein, having the indicated number of carbon atoms. The point of attachment of the alkylamino group is on the nitrogen. Examples of mono- and di-alkylamino groups include ethylamino, dimethylamino, and methyl-propyl-amino. Amino means —NH2.

The term “substituted”, as used herein, means that any one or more hydrogens on the designated atom or group is replaced with a selection from the indicated group, provided that the designated atom's normal valence is not exceeded. When the substituent is oxo (i.e., ═O) then 2 hydrogens on the atom are replaced. When an oxo group substitutes aromatic moieties, the corresponding partially unsaturated ring replaces the aromatic ring. For example, a pyridyl group substituted by oxo is a pyridone. Combinations of substituents and/or variables are permissible only if such combinations result in stable compounds or useful synthetic intermediates. A stable compound or stable structure is meant to imply a compound that is sufficiently robust to survive isolation from a reaction mixture, and subsequent formulation into an effective therapeutic agent.

Unless otherwise specified substituents are named into the core structure. For example, it is to be understood that when (cycloalkyl)alkyl is listed as a possible substituent the point of attachment of this substituent to the core structure is in the alkyl portion, or when arylalkyl is listed as a possible substituent the point attachment to the core structure is the alkyl portion.

Suitable groups that may be present on a “substituted” or “optionally substituted” position include, but are not limited to, halogen; cyano; hydroxyl; nitro; azido; alkanoyl (such as a C2-C6 alkanoyl group such as acyl or the like); carboxamido; alkyl groups (including cycloalkyl groups) having 1 to about 8 carbon atoms, or 1 to about 6 carbon atoms; alkenyl and alkynyl groups including groups having one or more unsaturated linkages and from 2 to about 8, or 2 to about 6 carbon atoms; alkoxy groups having one or more oxygen linkages and from 1 to about 8, or from 1 to about 6 carbon atoms; aryloxy such as phenoxy; alkylthio groups including those having one or more thioether linkages and from 1 to about 8 carbon atoms, or from 1 to about 6 carbon atoms; alkylsulfinyl groups including those having one or more sulfinyl linkages and from 1 to about 8 carbon atoms, or from 1 to about 6 carbon atoms; alkylsulfonyl groups including those having one or more sulfonyl linkages and from 1 to about 8 carbon atoms, or from 1 to about 6 carbon atoms; aminoalkyl groups including groups having one or more N atoms and from 1 to about 8, or from 1 to about 6 carbon atoms; aryl having 6 or more carbons and one or more rings, (e.g., phenyl, biphenyl, naphthyl, or the like, each ring either substituted or unsubstituted aromatic); arylalkyl having 1 to 3 separate or fused rings and from 6 to about 18 ring carbon atoms, with benzyl being an exemplary arylalkyl group; arylalkoxy having 1 to 3 separate or fused rings and from 6 to about 18 ring carbon atoms, with benzyloxy being an exemplary arylalkoxy group; or a saturated, unsaturated, or aromatic heterocyclic group having 1 to 3 separate or fused rings with 3 to about 8 members per ring and one or more N, O or S atoms, e.g. coumarinyl, quinolinyl, isoquinolinyl, quinazolinyl, pyridyl, pyrazinyl, pyrimidinyl, furanyl, pyrrolyl, thienyl, thiazolyl, triazinyl, oxazolyl, isoxazolyl, imidazolyl, indolyl, benzofuranyl, benzothiazolyl, tetrahydrofuranyl, tetrahydropyranyl, piperidinyl, morpholinyl, piperazinyl, and pyrrolidinyl. Such heterocyclic groups may be further substituted, e.g. with hydroxy, alkyl, alkoxy, halogen and amino.

Disclosed herein are resist polymers that can be used in photoresist compositions for reducing line width roughness and improving process window in advanced photoresist formulations. In an embodiment, the resist polymer comprises a copolymer that contains a first repeat unit and a second repeat unit, where the first repeat unit contains an acid labile group and where the second repeat unit is derived from the polymerization of the structure of formula (1) below:

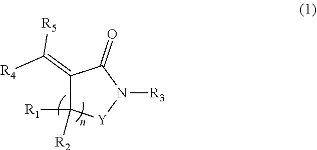

wherein R₁, R₂ and R₃ are each independently hydrogen, a halogen, a substituted or unsubstituted C₁ to C₁₂ alkyl group or C₃ to C₁₂ cycloalkyl group optionally containing an ether group, a carbonyl group, an ester group, a carbonate group, an amine group, an amide group, a urea group, a sulfate group, a sulfone group, a sulfoxide group, an N-oxide group, a sulfonate group, a sulfonamide group, or a combination thereof, a substituted or unsubstituted C₆ to C₁₄ aryl group, or C₃ to C₁₂ heteroaryl group, wherein the substitution is halogen, hydroxyl, cyano, nitro, C₁ to C₁₂ alkyl group, C₁ to C₁₂ haloalkyl group, C₁ to C₁₂ alkoxy group, C₃ to C₁₂ cycloalkyl group, amino, C₂-C₆ alkanoyl, carboxamido, a substituted or unsubstituted C₆ to C₁₄ aryl group, or C₃ to C₁₂ heteroaryl group;
wherein R₁ and R₂ together optionally form a ring;
wherein Y is chosen from carbonyl, sulfonyl, or substituted or unsubstituted methylene,
wherein Y and R₂ together optionally form a substituted or unsubstituted 4-7 member monocyclic ring or a substituted or unsubstituted 9-12 member bicyclic ring (including fused and spiro), the monocyclic and bicyclic rings optionally containing 1, 2, or 3 heteroatoms chosen from N, O, and S, wherein each ring is saturated, unsaturated, or aromatic, and wherein each ring optionally contains an ether group, a carbonyl group, an ester group, a carbonate group, an amine group, an amide group, a urea group, a sulfate group, a sulfone group, a sulfoxide group, an N-oxide group, a sulfonate group, a sulfonamide group, or a combination thereof, wherein the substitution on the ring is halogen, hydroxyl, cyano, nitro, C₁ to C₁₂ alkyl group, C₁ to C₁₂ haloalkyl group, C₁ to C₁₂ alkoxy group, C₃ to C₁₂ cycloalkyl group, amino, C₂-C₆ alkanoyl, carboxamido, a substituted or unsubstituted C₆ to C₁₄ aryl group, or C₃ to C₁₂ heteroaryl group; and wherein R₄ and R₅ are each independently hydrogen, halogen, a substituted or unsubstituted C₁ to C₃ alkyl group where the substitution is halogen; and wherein n=1-3.

In an embodiment, the second repeat unit is a cyclic lactam and/or a cyclic imide having an exocyclic polymerizable group. In an embodiment, the resist polymer may contain a plurality of repeat units that contain a cyclic lactam and/or a cyclic imide (that have the exocyclic polymerizable group) that are different from each other.

The resist polymer disclosed herein is also sometimes referred to as a resist copolymer. The first repeat unit and the second repeat unit are covalently or ionically bonded to form the copolymer. The copolymer may be a block copolymer, a random copolymer, a star block copolymer, a gradient copolymer, an alternating copolymer, or a combination thereof. In an embodiment, the photoresist composition containing the copolymer may also be blended with one or more polymers. Polymers that can be blended with the resist polymer are preferably compatible with either the first repeat unit, the second repeat unit and/or the third repeat unit. In a preferred embodiment, the resist polymer is a random copolymer.

The resist polymers disclosed herein are advantageous in that the cyclic lactam and cyclic imide repeat units serve a dual purpose, acting as both a polar functional group to modulate acid diffusion and also serve as a high T_{g} (glass transition temperature) component in the resist polymer backbone to improve line width roughness and process window. The use of cyclic lactam or cyclic imide repeat units in the resist polymer improves polymer solubility in solvents that are used in the photoresist composition when compared with other commercially available resist compositions that contain traditional lactone or polar polymers. The improved solubility in an organic solvent for the polymers disclose herein make them suitable for use in solvent developable negative tone resist compositions.

In an embodiment, the resist polymer can include (in addition to the second repeat unit that has the structure shown in formula (1) above) a plurality of repeat units that are different from each other, where each of the different repeat units has an acid labile group. In an embodiment, the resist polymer can include (in addition to the second repeat unit that has the structure shown in formula (1) above) a plurality of repeat units that are different from each other, where at least one of the different repeat units has an acid labile group. In an embodiment, the resist polymer can include in addition to the second repeat unit that has the structure shown in formula (1) above, two or more monomer repeat units (e.g., a first repeat unit and a third repeat unit) that are different from each other, where at least one of the first or the third repeat unit has an acid labile group. In an embodiment, in addition to the second repeat unit that has the structure shown in formula (1) above, both the first and the third repeat units in the resist polymer are different from each other and each contains an acid labile group.

In some embodiments, the resist polymer can include two or more monomer repeat units such as, for example, a first repeat unit, a third repeat unit and/or a fourth repeat unit, where one of the first, third or fourth repeat unit has an acid labile group in addition to the second repeat unit that comprises a cyclic lactam and/or a cyclic imide having an exocyclic polymerizable group. As noted above, the first repeat unit, the second repeat unit, the third repeat unit and/or the fourth repeat units are covalently or ionically bonded to each other to form the resist polymer. In some embodiments, the resist copolymer can comprise a repeat unit that decomposes upon irradiation to form an acid.

The resist polymer may also contain more than one repeat unit that has a cyclic lactam and/or a cyclic imide, where each repeat unit is chemically different from another repeat unit that has a cyclic lactam and/or a cyclic imide. For example, the resist polymer may have one repeat unit that contains either a cyclic lactam and/or a cyclic imide and an additional repeat unit that contains a lactone or a sultone.

Examples of the second repeat unit (that have the structure shown in formula (1) above) include lactam monomers and cyclic imide monomers shown below in the formula (2):

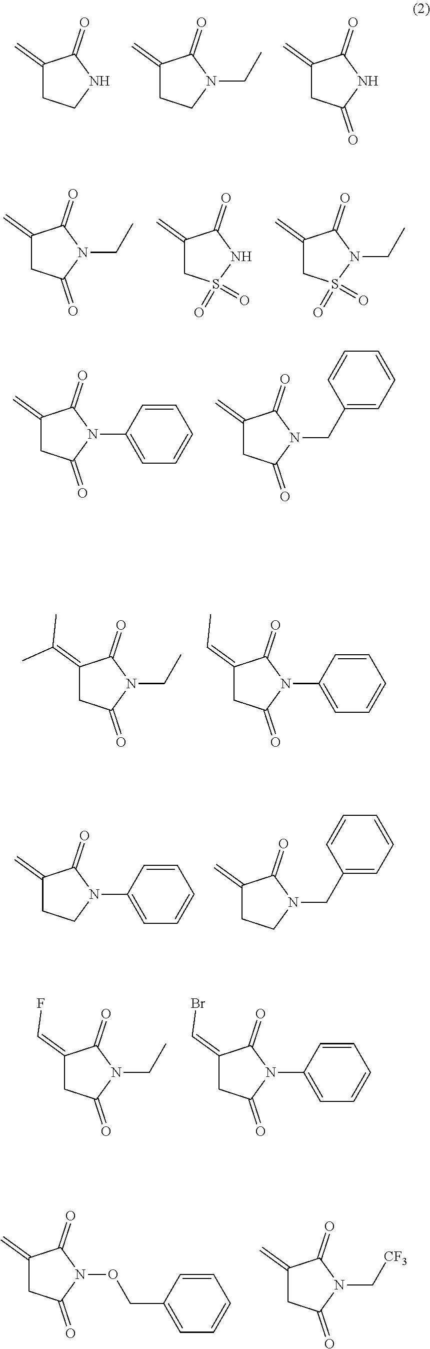

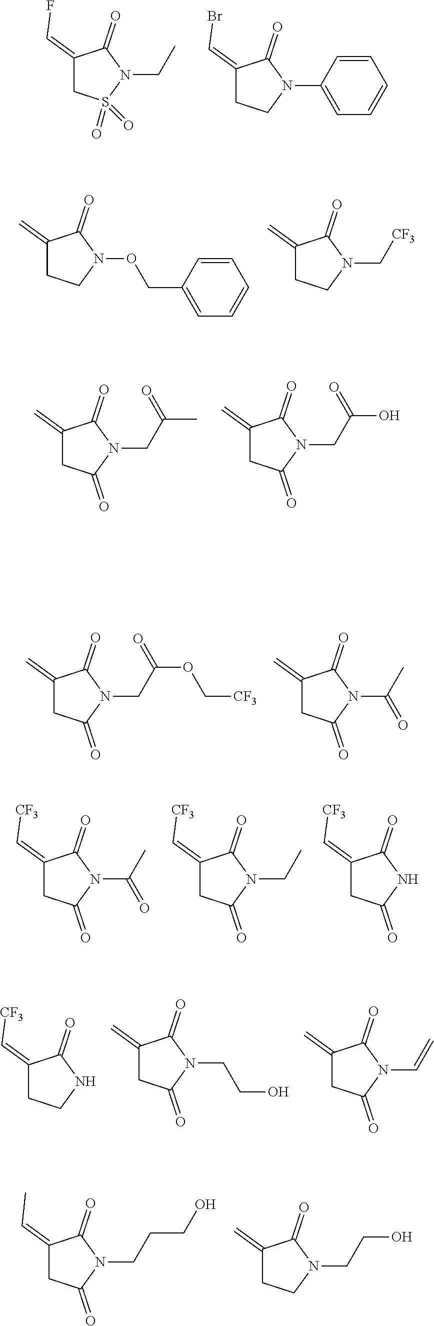

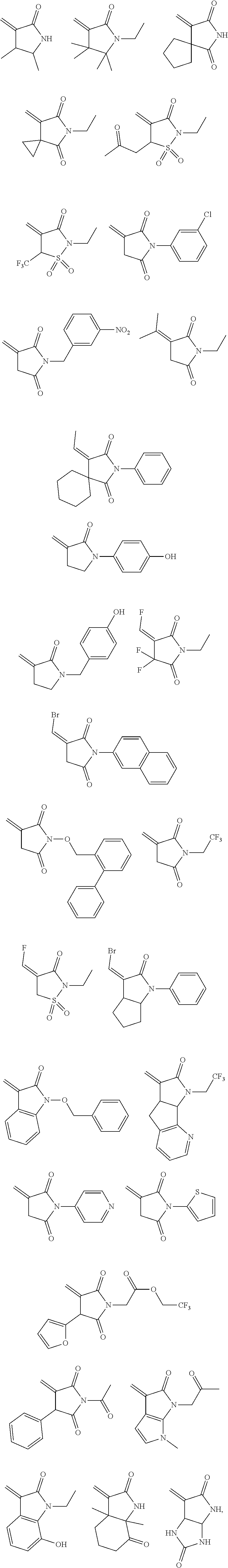

or a combination thereof.

Preferred lactam or imide monomers for use in the resist polymer are shown below in formula (3);

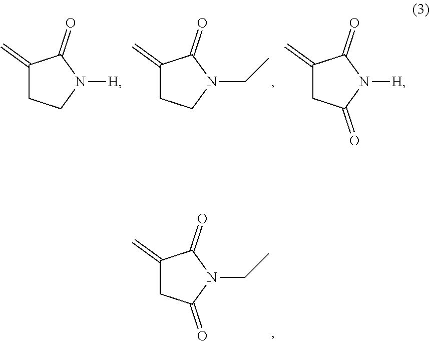

or a combination thereof.

In a preferred embodiment, the second repeat unit has the structure:

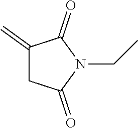

In an embodiment, the molar ratio of the second repeat unit to the sum of the other repeat units (first repeat unit, third repeat unit, fourth repeat unit and/or fifth repeat unit) is 5% to 30%, preferably 6% to 25%, and more preferably 10% to 20%. In an embodiment, the second repeat unit constitutes 5 to 30%, preferably 5 to 25%, and more preferably 10 to 20%, of the total number of repeat units in the resist copolymer.

In an embodiment, the weight ratio of the second repeat unit to the sum of the other repeat units (first repeat unit, third repeat unit and/or the fourth repeat unit) in the resist polymer is 1:3 to 1:10, preferably 1:4 to 1:8, and more preferably 1:5 to 1:7. In another embodiment, the weight ratio of the atomic weight of the second repeat unit to the total atomic weight of the resist polymer is 0.05 to 0.20, preferably 0.08 to 0.16, and preferably 0.09 to 0.15.

In yet another embodiment, the second repeat unit is used in the resist copolymer in an amount of 5 to 60 wt %, preferably in an amount of 8 to 35 wt %, and more preferably in an amount of 10 to 25 wt %, based on the total weight of the resist copolymer.

As noted above, one of the first repeat unit, the third repeat unit, and/or the fourth repeat unit has an acid labile group. It is to be noted that while this disclosure refers to a first, third and fourth repeat units, there can be additional repeat units such as a fifth, sixth, and so on, repeat units, where each repeat unit is chemically different from the other repeat units in the resist polymer. The acid labile group may be a tertiary alkyl ester, an acetal group or a ketal group, or a combination thereof. Examples of the repeat units (e.g., the first repeat unit, the third repeat unit and/or the fourth repeat unit) that have an acid labile group are (meth)acrylates and/or vinyl aromatic monomers.

In an embodiment, the first repeat unit having the labile acid group has having a structure represented by formula (4):

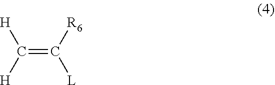

where R₆ is a hydrogen or an alkyl group having 1 to 10 carbon atoms and where L comprises a carbonyl group (e.g., species including aldehydes; ketones; carboxylic acids and carboxylic esters such as, for example, (meth)acrylic acids and (meth)acrylates), a single bond (e.g., a vinyl ether), or an aromatic unit (e.g., styrene or its derivatives). In an embodiment, the carboxylic ester is a tertiary alkyl ester.

In an embodiment, when L comprises a carbonyl group, the repeat unit containing the acid labile group has the structure represented by formula (5a) below:

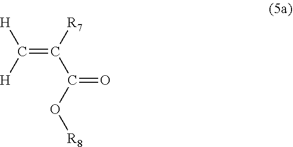

where R₇ is a hydrogen or an alkyl or haloalkyl group having 1 to 10 carbon atoms and where R₈ is a linear or branched substituted or unsubstituted alkyl group having 1 to 10 carbon atoms, a substituted or unsubstituted monocyclic or polycyclic cycloalkyl group having 3 to 14 carbon atoms or a tertiary alkyl ester. The cycloalkyl groups may contain one or more heteroatoms such as oxygen, sulfur, nitrogen, or phosphorus. Combinations or heteroatoms may also be used. For example, the cycloalkyl group may contain an oxygen and a nitrogen heteroatom. Repeat units having the structure of formula (5a) which do not have acid labile groups may also be used in the resist polymer, so long as the resist polymer has at least one repeat unit that has an acid labile group.

Examples of other monomers that contain an acid labile group (e.g., a carbonyl group) below in formula (6):

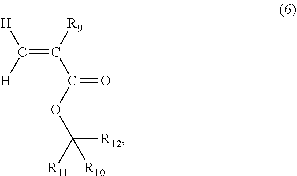

where R₉ is a hydrogen or an alkyl or haloalkyl group having 1 to 10 carbon atoms, and where R₁₀, R₁₁ and R₁₂ may be the same or different and are selected from a linear or branched substituted or unsubstituted alkyl group having 1 to 10 carbon atoms, a substituted or unsubstituted monocyclic or polycyclic cycloalkyl group having 3 to 14 carbon atoms, an aryl or a heteroaryl. The cycloalkyl groups may contain one or more heteroatoms such as oxygen, sulfur, nitrogen, or phosphorus. Combinations or heteroatoms may also be used. For example, the cycloalkyl group may contain an oxygen and a nitrogen heteroatom. In an embodiment, either R₁₀ and R₁₁ or R₁₀ and R₁₂ may optionally form a ring.

In an embodiment, R₁₀, R₁₁ and R₁₂ in the formula (6) may be the same or different and comprise hydrogen, a substituted or unsubstituted alkyl group having 2 to 8 carbon atoms that may be linear or branched or a substituted or unsubstituted cycloalkyl group having 4, 5 or 6 carbon atoms that may contain branches.

Examples of monomers that contain a carbonyl acid labile group include the following:

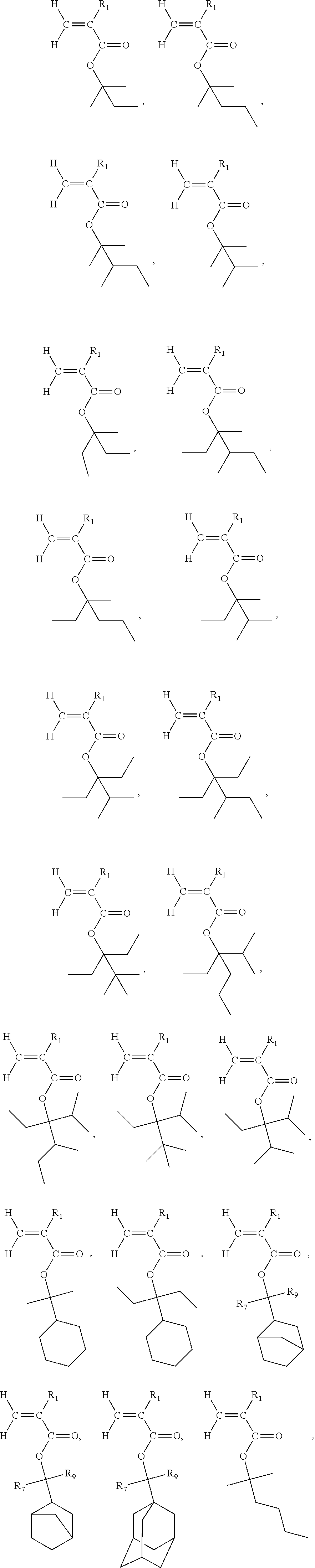

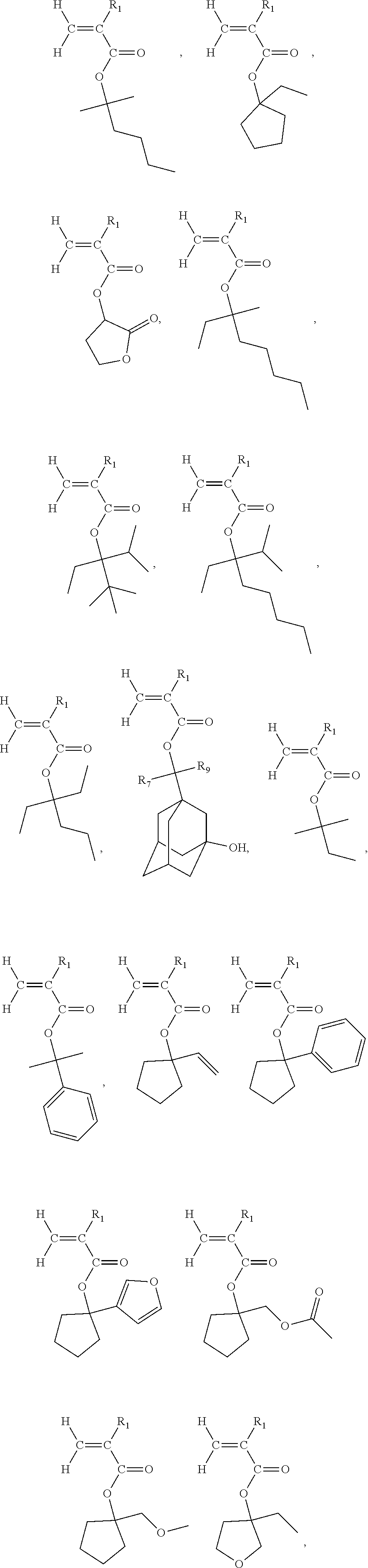

or a combination thereof; wherein where R is a hydrogen or an alkyl or haloalkyl group having 1 to 10 carbon atoms, a halogen, or a haloalkyl group having 1 to 10 carbon atoms, and wherein R₇ is an alkyl group which may include a branched structure having 1 to 10 carbon atoms or a monocyclic or polycyclic cycloalkyl group having 3 to 14 carbon atoms; and R₉ is an alkyl group which may include a branched structure having 1 to 10 carbon atoms or a monocyclic or polycyclic cycloalkyl group having 3 to 14 carbon atoms. Preferred halogen atoms are fluorine atoms and a preferred haloalkyl group includes a fluoroalkyl group.

In an embodiment, when L in formula (4) comprises more than one carbon atom, the repeat unit containing the acid labile group has the structure represented by formula (5b) below

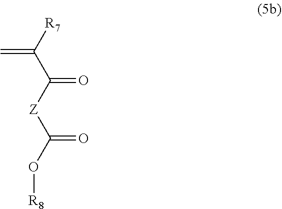

wherein Z is a linking unit comprising at least one carbon atom and at least one heteroatom, where R₇ is a hydrogen atom or an alkyl group having 1 to 10 carbon atoms; and wherein R is an alkyl group which may include a branched structure having 1 to 10 carbon atoms, a monocyclic or polycyclic cycloalkyl group having 3 to 14 carbon atoms or a tertiary alkyl ester. In an embodiment, Z can have 2 to 10 carbon atoms. In another embodiment, Z can be CH₂—C(═O)—O—).

Specific example of repeat units that have the structure of formula 5b are the following:

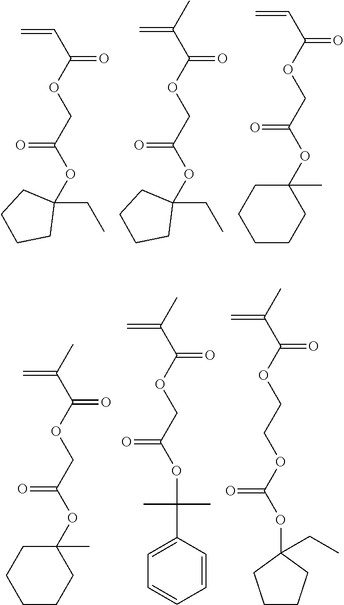

Illustrative acid-labile acetal- and ketal-substituted monomers also include:

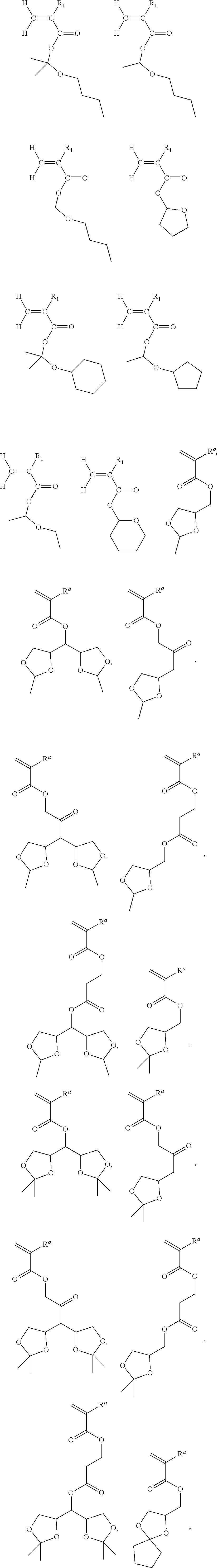

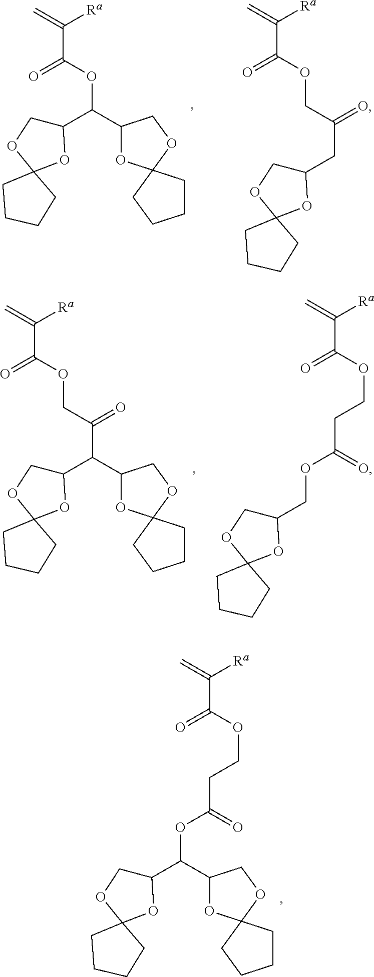

and combinations thereof, wherein R^{a} is —H, —F, —CH₃, or —CF₃.

In another embodiment, when L is an aromatic unit, the acid labile repeat unit may be a vinyl aromatic unit having the structure of formula (7):

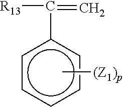

(7), wherein R₁₃ is hydrogen, an alkyl or halogen; Z₁ is a hydroxyl or optionally a hydrogen, a halogen, an alkyl, an aryl, or a fused aryl; and p is from 1 to about 5. In an embodiment, Z₁ is preferably a hydroxyl.

The vinyl aromatic monomers that can be reacted to produce the resist polymer include styrenes, alkylstyrenes, hydroxystyrenes, or styrenes substituted with halogens. Examples of suitable alkylstyrenes are o-methylstyrene, p-methylstyrene, m-methylstyrene, α-methylstyrene, o-ethylstyrene, m-ethylstyrene, p-ethylstyrene, α-methyl-p-methylstyrene, 2,4-dimethylstyrene, p-tert-butylstyrene, 4-tert-butylstyrene, or the like, or a combination comprising at least one of the foregoing alkylstyrene monomers. Examples of styrenes substituted with halogens include chlorostyrene, fluorostyrene, hydroxyfluorostyrene, or a combination thereof.

The acid labile repeat units may be present in an amount of 5 to 70 mol %, preferably 20 to 60 mol %, based on the total number of moles of the resist polymer, while the repeat units that contain cyclic lactams or cyclic imides are present in an amount of 5 to 30 mol %, preferably 10 to 20 mol %, based on the total number of moles of the resist polymer.

In one embodiment, in one method of manufacturing the resist copolymer, the unreacted acid labile repeat units (the first, third, fourth and/or fifth repeat units) along with a stoichiometric amount of the cyclic lactam and/or cyclic imide repeat units are introduced into a reaction vessel. A suitable solvent that can solvate both the acid labile repeat units and the lactam and/or imide repeat units may be added to the reactor along with a suitable initiator. Catalysts that activate or increase the rate of reactor may also be added to the reactor. As noted above, units that do not contain acid labile groups (such as lactones, sultones, and the like) may be used in conjunction with the acid labile repeat units (repeat units that contain acid labile groups) and the cyclic lactams and cyclic imides to form the resist polymer.

It is to be noted that the acid labile repeat units and the cyclic lactam and cyclic imide repeat units may be manufactured in a separate process or may be purchased commercially prior to the reaction to produce the resist polymer. Commercially available monomers may be purified prior to being reacted to form the resist polymer.

The polymerizing initiator is added to the reaction vessel along with an optional catalyst and the vessel temperature is raised to facilitate a reaction to form the resist polymer. After a suitable period of time, the temperature is gradually reduced and the resulting copolymer is separated from the solution and dried. The polymer may be purified by washing prior to being used as in a resist composition.

Exemplary resist copolymers are shown in the formulas (8) through (11) below:

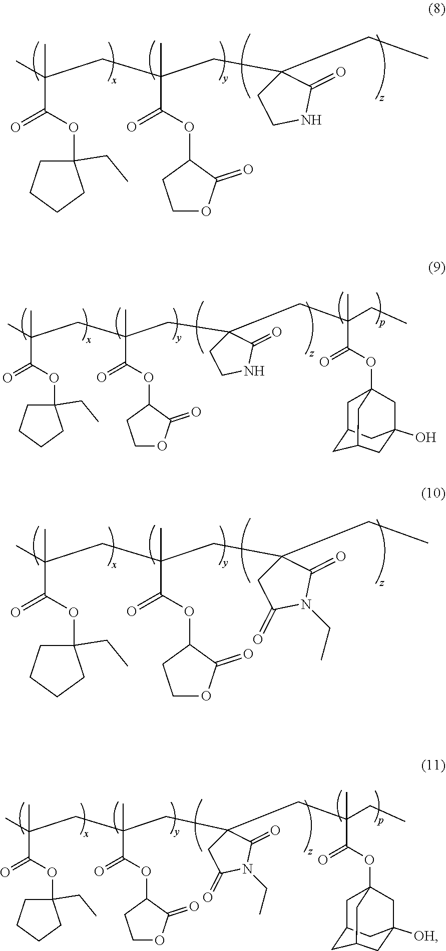

or a combination thereof.

The number of repeat units of the first repeat unit (the acid labile repeat units) in the resist polymer may be 20 to 60, preferably 30 to 50. The number of repeat units of the second repeat unit (the lactam or imide repeat unit) in the resist polymer may be 10 to 30, preferably 15 to 25. If a third repeat unit (the acid labile repeat unit) is used in the resist polymer, the number of third repeat units may be 20 to 60, preferably 30 to 50. If a fourth repeat unit (the acid labile repeat unit) is used in the resist polymer, the number of fourth repeat units may be 5 to 15, preferably 8 to 12. In the formulas (6) through (9), “x” may be 20 to 60, preferably 30 to 50, “y” may be 20 to 60, preferably 30 to 50, may be 5 to 15, preferably 8 to 12 and z may be 10 to 30, preferably 15 to 25.

Exemplary resist copolymers used in the resist composition produced by the aforementioned reaction are shown below in the formula (12).

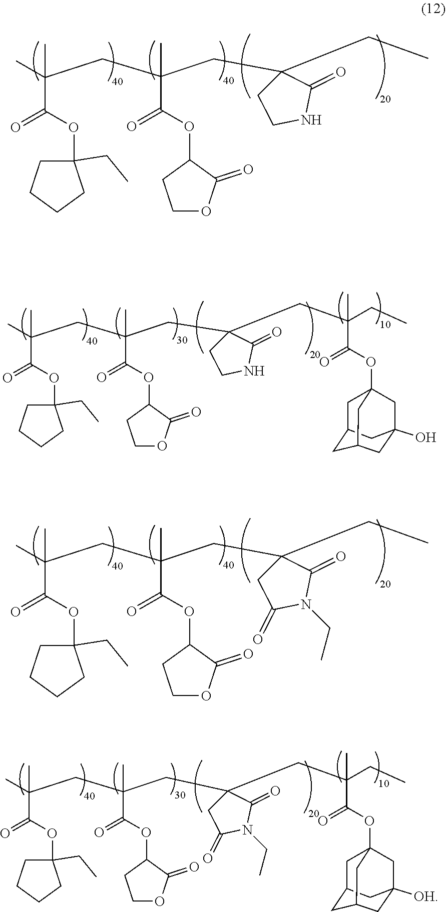

In an embodiment, a resist composition (discussed in detail below) may contain one or more of the polymers shown in formula (12).

The resist copolymer may further include a repeating unit derived from a monomer comprising a photoacid generator. The photoacid generator monomer including a polymerizable group may be represented by formula (13):

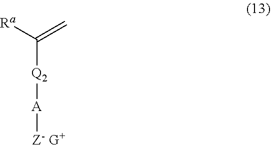

In formula (13), each R may independently be H, F, C₁₋₁₀ alkyl, or C₁₋₁₀ fluoroalkyl. As used throughout this specification, “fluoro” or “fluorinated” means that one or more fluorine groups are attached to the associated group. For example, by this definition and unless otherwise specified, “fluoroalkyl” encompasses monofluoroalkyl, difluoroalkyl, or the like, as well as perfluoroalkyl in which substantially all carbon atoms of the alkyl group are substituted with fluorine atoms; similarly, “fluoroaryl” means monofluoroaryl, perfluoroaryl, and the like. “Substantially all” in this context means greater than or equal to 90%, preferably greater than or equal to 95%, and still more preferably greater than or equal to 98% of all atoms attached to carbon are fluorine atoms.

In formula (13), Q₂ may be a single bond or an ester-containing or non-ester containing, fluorinated or non-fluorinated group selected from C₁₋₂₀ alkyl, C₃₋₂₀ cycloalkyl, C₆₋₂₀ aryl, and C₇₋₂₀ aralkyl. For example, where an ester is included, the ester may form a connective link between Q₂ and the point of attachment to the double bond. In this way, where Q₂ is an ester group, formula (13) may be a (meth)acrylate monomer. Where an ester is not included, Q₂ may be aromatic, so that formula (13) may be, for example, a styrenic monomer or vinyl naphthoic monomer.

Also, in formula (13), A may be an ester-containing or non ester-containing, fluorinated or non-fluorinated group selected from C₁₋₂₀ alkyl, C₃₋₂₀ cycloalkyl, C₆₋₂₀ aryl, or C₇₋₂₀ aralkyl. Useful A groups may include fluorinated aromatic moieties, straight chain fluoroalkyl, or branched fluoroalkyl esters. For example, A may be a —[(C(R^{e})₂)ₓ(═O)O]_{c}—(C(R^{f})₂)_{y}(CF₂)₂— group, or an o-, m- or p-substituted —C₆R^{g}₄— group, where each R^{e}, R^{f}, and R^{g} are each independently H, F, C₁₋₆ fluoroalkyl, or C₁₋₆ alkyl, c may be 0 or 1, x may be an integer of 1 to 10, y and z may independently be integers of from 0 to 10, and the sum of y+z may be at least 1.

Also, in formula (13), Z may be an anionic group including a sulfonate (—SO₃—), the anion of a sulfonamide (—SO₂(N⁻)R′ where R′ may be a C₁₋₁₀ alkyl or C₆₋₂₀ aryl, or the anion of a sulfonimide. Where Z is a sulfonimide, the sulfonimide may be an asymmetric sulfonimide having the general structure A-SO₂—(N⁻)—SO₂—Y², where A is as described above, and Y² may be a straight chain or branched C₁₋₁₀ fluoroalkyl group. For example, the Y² group may be a C₁₋₄ perfluoroalkyl group, which may be derived from the corresponding perfluorinated alkanesulfonic acid, such as trifluoromethanesulfonic acid or perfluorobutanesulfonic acid.

In an embodiment, the monomer of formula (13) may have the structure of formula (13a) or (13b):

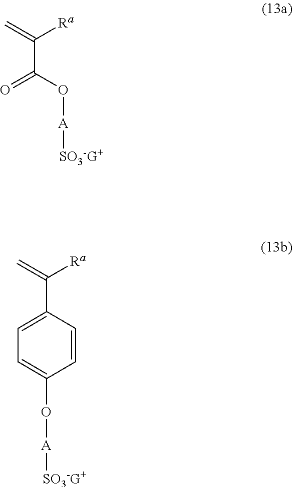

wherein A and R^{a} are as defined for formula (13). In formulae (13), (13a), and (13b), G may have formula (13c):

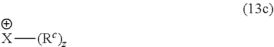

wherein X, R^{c}, and z are the same as described in the embodiments above. In an embodiment, the copolymer may include a polymerized product having any of the following structures:

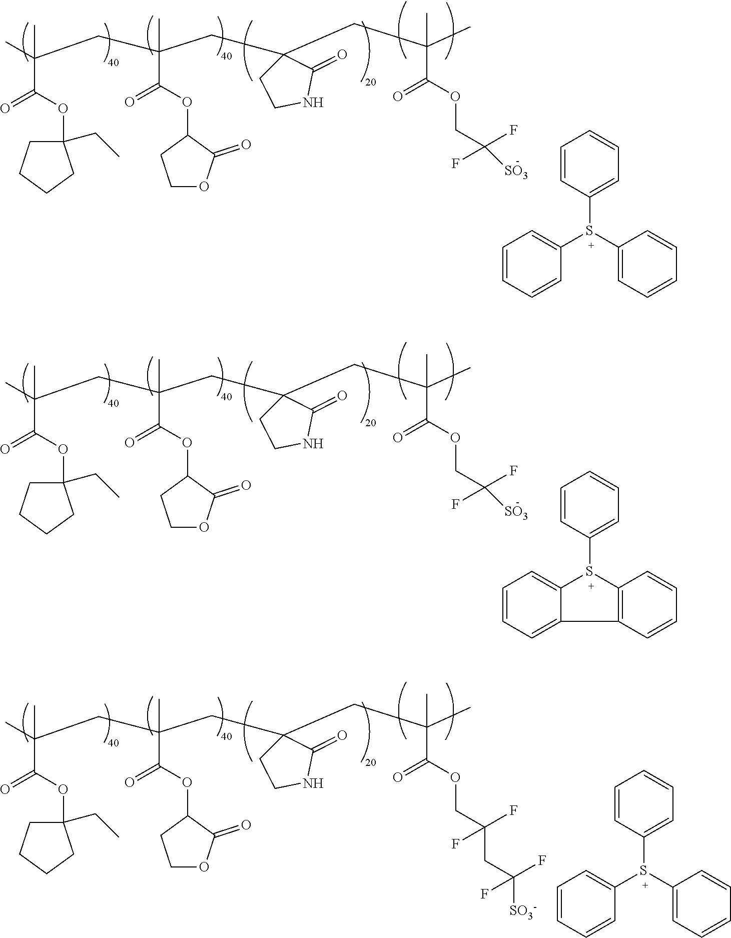

As noted above, the resist polymer may be used in a resist composition that is then disposed on a substrate to pattern the substrate. The resist composition is then prepared by mixing and dissolving the resist polymer in a suitable solvent. In addition to the resist polymer and the solvent, the resist composition may optionally contain a photoacid generator, a surfactant, an optional additive polymer that comprises one or more fluorinated monomeric units to form a resist composition.

In some embodiments, the resist composition in solution comprises the polymer in an amount of 50 to 99 weight percent, specifically 55 to 95 weight percent, more specifically 65 to 90 based on the weight of the total solids. It will be understood that “polymer” used in this context of a component in a resist may mean only the copolymer disclosed herein, or a combination of the copolymer with another polymer useful in a photoresist. It will be understood that total solids includes polymer, photo-destroyable base, quencher, surfactant, any added PAG, and any optional additives, exclusive of solvent.

Solvents generally suitable for dissolving, dispensing, and coating include anisole, alcohols including ethyl lactate, methyl 2-hydroxybutyrate (HBM), 1-methoxy-2-propanol (also referred to as propylene glycol methyl ether, PGME), and 1-ethoxy-2 propanol, esters including n-butyl acetate, 1-methoxy-2-propyl acetate (also referred to as propylene glycol methyl ether acetate, PGMEA), methoxyethyl propionate, ethoxyethyl propionate, and gamma-butyrolactone, ketones including cyclohexanone and 2-heptanone, and combinations thereof.

The solvent amount can be, for example, 70 to 99 weight percent, specifically 85 to 98 weight percent, based on the total weight of the resist composition.

As noted above, the resist composition may contain a fluorine containing polymer. In an embodiment, the fluorine containing polymer may be derived from the polymerization of monomers having the structure of formula (14).

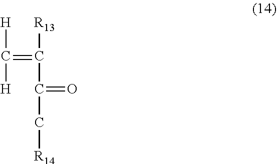

wherein in formula (14), R₁₃ is a hydrogen or an alkyl group having 1 to 10 carbon atoms and R₁₄ is a C₂₋₁₀ fluoroalkyl group. Examples of the fluorine containing monomer are trifluoroethyl methacrylate, dodecafluoroheptylmethacrylate, or a combination thereof.

The fluorinated polymer is present in the resist composition in an amount of 0.01 to 10 wt %, based on the total weight of the resist composition. In a preferred embodiment, the fluorinated polymer is present in the resist composition in an amount of 1 to 5 wt %, based on the total weight of the resist composition.

The resist composition may also contain photoacid generators. Photoacid generators generally include those photoacid generators suitable for the purpose of preparing photoresists. Photoacid generators include, for example, non-ionic oximes and various onium ion salts. Onium ions include, for example, unsubstituted and substituted ammonium ions, unsubstituted and substituted phosphonium ions, unsubstituted and substituted arsonium ions, unsubstituted and substituted stibonium ions, unsubstituted and substituted bismuthonium ions, unsubstituted and substituted oxonium ions, unsubstituted and substituted sulfonium ions, unsubstituted and substituted selenonium ions, unsubstituted and substituted telluronium ions, unsubstituted and substituted fluoronium ions, unsubstituted and substituted chloronium ions, unsubstituted and substituted bromonium ions, unsubstituted and substituted iodonium ions, unsubstituted and substituted aminodiazonium ions (substituted hydrogen azide), unsubstituted and substituted hydrocyanonium ions (substituted hydrogen cyanide), unsubstituted and substituted diazenium ions (RN=N+R2), unsubstituted and substituted iminium ions (R2C=N+R2), quaternary ammonium ions having two double-bonded substituents (R=N+=R), nitronium ion (NO2+), bis(trarylphosphine)iminium ions ((Ar3P)2N+), unsubstituted or substituted tertiary ammonium having one triple-bonded substituent (R≡NH+), unsubstituted and substituted nitrilium ions (RC≡NR+), unsubstituted and substituted diazonium ions (N≡N+R), tertiary ammonium ions having two partially double-bonded substituents (R [symbol] N+H [symbol] R), unsubstituted and substituted pyridinium ions, quaternary ammonium ions having one triple-bonded substituent and one single-bonded substituent (R≡N+R), tertiary oxonium ions having one triple-bonded substituent (R≡O+), nitrosonium ion (N≡O+), tertiary oxonium ions having two partially double-bonded substituents (R [symbol] O+ [symbol] R), pyrylium ion (C5H5O+), tertiary sulfonium ions having one triple-bonded substituent (R≡S+), tertiary sulfonium ions having two partially double-bonded substituents (R [symbol] S+ [symbol] R), and thionitrosonium ion (N≡S+). In some embodiments, the onium ion is selected from unsubstituted and substituted diaryiodonium ions, and unsubstituted and substituted triarylsulfonium ions. Examples of suitable onium salts can be found in U.S. Pat. No. 4,442,197 to Crivello et al., U.S. Pat. No. 4,603,101 to Crivello, and U.S. Pat. No. 4,624,912 to Zweifel et al.

Suitable photoacid generators are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable photoacid generators with specific examples are further described in U.S. Pat. No. 8,431,325 to Hashimoto et al. in column 37, lines 11-47 and columns 41-91.

Another a preferred embodiment the photoacid generator is an ionic compound represented by formula G⁺A⁻, wherein A⁻ is a non-polymerizable organic anion and G⁺ has formula (VI):

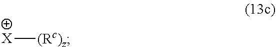

wherein in formula (13c), X may be S or I, each R^{c} may be halogenated or non-halogenated, and is independently a C₁₋₃₀ alkyl group; a polycyclic or monocyclic C₃₋₃₀ cycloalkyl group; a polycyclic or monocyclic C₄₋₃₀ aryl group, wherein when X is S, one of the R^{c} groups is optionally attached to one adjacent R^{c} group by a single bond, and z is 2 or 3, and wherein when X is I, z is 2, or when X is S, z is 3.

For example, cation G⁺ may have formula (13d), (13e), or 13f):

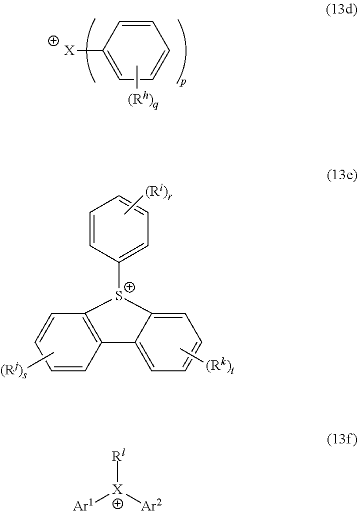

wherein X is I or S, R^{h}, Rⁱ, R^{j}, and R^{k} are unsubstituted or substituted and are each independently hydroxy, nitrile, halogen, C₁₋₃₀ alkyl, C₁₋₃₀ fluoroalkyl, C₃₋₃₀ cycloalkyl, C₁₋₃₀ fluorocycloalkyl, C₁₋₃₀ alkoxy, C₃₋₃₀ alkoxycarbonylalkyl, C₃₋₃₀ alkoxycarbonylalkoxy, C₃₋₃₀ cycloalkoxy, C₅₋₃₀ cycloalkoxycarbonylalkyl, C₅₋₃₀ cycloalkoxycarbonylalkoxy, C₁₋₃₀ fluoroalkoxy, C₃₋₃₀ fluoroalkoxycarbonylalkyl, C₃₋₃₀ fluoroalkoxycarbonylalkoxy, C₃₋₃₀ fluorocycloalkoxy, C₅₋₃₀ fluorocycloalkoxycarbonylalkyl, C₅₋₃₀ fluorocycloalkoxycarbonylalkoxy, C₆₋₃₀ aryl, C₆₋₃₀ fluoroaryl, C₆₋₃₀ aryloxy, or C₆₋₃₀ fluoroaryloxy, each of which is unsubstituted or substituted;

Ar¹ and Ar² are independently C₁₀₋₃₀ fused or singly bonded polycyclic aryl groups;

R¹ is a lone pair of electrons where X is I, or a C₆₋₂₀ aryl group where X is S;

p is an integer of 2 or 3, wherein when X is I, p is 2, and where X is S, p is 3,

q and r are each independently an integer from 0 to 5, and

s and t are each independently an integer from 0 to 4.

In formulae (13c), (13d), or (13f), at least one of Rh, Ri, Rj, and Rk may be an acid-cleavable group. In an embodiment, the acid-cleavable group may be (i) a tertiary C₁₋₃₀ alkoxy (for example, a tert-butoxy group), a tertiary C₃₋₃₀ cycloalkoxy group, a tertiary C₁₋₃₀ fluoroalkoxy group, (ii) a tertiary C₃₋₃₀ alkoxycarbonylalkyl group, a tertiary C₅₋₃₀ cycloalkoxycarbonylalkyl group, a tertiary C₃₋₃₀ fluoroalkoxycarbonylalkyl group, (iii) a tertiary C₃₋₃₀ alkoxycarbonylalkoxy group, a tertiary C₅₋₃₀ cycloalkoxycarbonylalkoxy group, a tertiary C₃₋₃₀ fluoroalkoxycarbonylalkoxy group, or (iv) a C₂₋₃₀ acetal group including moiety —O—C(R₁₁R₁₂)—O— (wherein R₁₁R₁₂ are each independently hydrogen or a C1-30.

Two specific PAGS are the following PAG1 and PAG2, the preparation of which is described in U.S. Patent Application Ser. No. 61/701,588, filed Sep. 15, 2012.

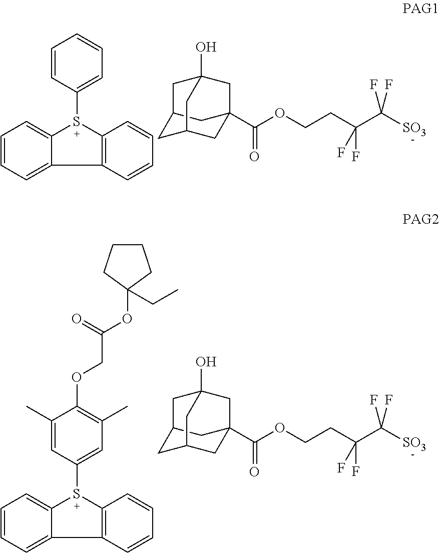

Other suitable sulfonate PAGS include sulfonated esters and sulfonyloxy ketones. See J. of Photopolymer Science and Technology, 4(3):337-340 (1991), for disclosure of suitable sulfonate PAGS, including benzoin tosylate, t-butylphenyl α-(p-toluenesulfonyloxy)-acetate and t-butyl α-(p-toluenesulfonyloxy)-acetate. Preferred sulfonate PAGs are also disclosed in U.S. Pat. No. 5,344,742 to Sinta et al.

Other useful photoacid generators include the family of nitrobenzyl esters, and the s-triazine derivatives. Suitable s-triazine photoacid generators are disclosed, for example, in U.S. Pat. No. 4,189,323. Halogenated non-ionic, photoacid generating compounds are also suitable such as, for example, 1,1-bis[p-chlorophenyl]-2,2,2-trichloroethane (DDT); 1,1-bis[p-methoxyphenyl]-2,2,2-trichloroetnane; 1,2,5,6,9,10-hexabromocyclodecane; 1,10-dibromodecane; 1,1-bis[p-chlorophenyl]-2,2-dichloroethane; 4,4-dichloro-2-(trichloromethyl)benzhydrol; hexachlorodimethyl sulfone; 2-chloro-6-(trichloromethyl)pyridine; o,o-diethyl-o-(3,5,6trichloro-2-pyridyl)phosphorothionate; 1,2,3,4,5,6-hexachlorocyclobexane; N(1,1-bis[p-chlorophenyl]-2,2,2-trichloroethyl)acetamide; tris[2,3-dibromopropyl]isocyanurate; 2,2-bis[p-chlorophenyl]-1,1-dichloroethylene; tris[trichloromethyl]s-triazine; and their isomers, analogs, homologs, and compounds. Suitable photoacid generators are also disclosed in European Patent Application Nos. 0164248 and 0232972. Photoacid generators that are particularly preferred for deep U.V. exposure include 1,1-bis(p-chlorophenyl)-2,2,2-trichloroethane (DDT); 1,1-bis(p-methoxyphenol)-2,2,2-trichloroethane; 1,1-bis(chlorophenyl)-2,2,2 trichloroethanol; tris(1,2,3-methanesulfonyl)benzene; and tris(trichloromethyl)triazine.

Photoacid generators may further include photo-destroyable bases. Photo-destroyable bases include photo-decomposable cations, and preferably those useful for preparing PAGs, paired with an anion of a weak (pKa>2) acid such as, for example, a C₁₋₂₀ carboxylic acid. Exemplary such carboxylic acids include formic acid, acetic acid, propionic acid, tartaric acid, succinic acid, cyclohexylcarboxylic acid, benzoic acid, salicylic acid, and other such carboxylic acids. Exemplary photo-destroyable bases include those combining cations and anions of the following structures where the cation is triphenylsulfonium or one of the following:

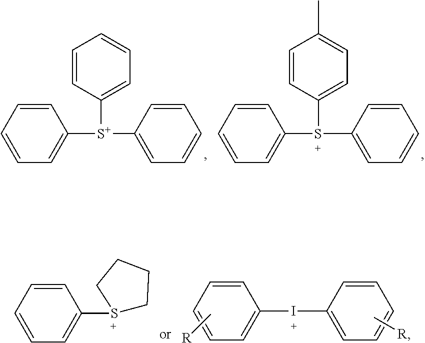

where R is independently H, a C₁₋₂₀ alkyl, a C₆₋₂₀ aryl, or a C₆₋₂₀ alkyl aryl, and the anion is

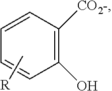

### RC(═O)—O—, or —OH,

where R is independently H, a C₁₋₂₀ alkyl, a C₁₋₂₀ alkoxyl, a C₆₋₂₀ aryl, or a C₆₋₂₀ alkyl aryl.

The resist composition can optionally include a photobase generator, including those based on non-ionic photo-decomposing chromophores such as, for example, 2-nitrobenzyl groups and benzoin groups. An exemplary photobase generator is ortho-nitrobenzyl carbamate.

The photoacid generator is included in the amounts of 0 to 50 weight percent, specifically 1.5 to 45 weight percent, more specifically 2 to 40 weight percent, based on the total weight of solids.

The resist composition can include a photoinitiator. Photoinitiators are used in the photoresist composition for initiating polymerization of the cross-linking agents by generation of free-radicals. Suitable free radical photoinitiators include, for example, azo compounds, sulfur containing compounds, metallic salts and complexes, oximes, amines, polynuclear compounds, organic carbonyl compounds and mixtures thereof as described in U.S. Pat. No. 4,343,885, column 13, line 26 to column 17, line 18; and 9,10-anthraquinone; 1-chloroanthraquinone; 2-chloroanthraquinone; 2-methylanthraquinone; 2-ethylanthraquinone; 2-tert-butylanthraquinone; octamethylanthraquinone; 1,4-naphthoquinone; 9,10-phenanthrenequinone; 1,2-benzanthraquinone; 2,3-benzanthraquinone; 2-methyl-1,4-naphthoquinone; 2,3-dichloronaphthoquinone; 1,4-dimethylanthraquinone; 2,3-dimethylanthraquinone; 2-phenylanthraquinone; 2,3-diphenylanthraquinone; 3-chloro-2-methylanthraquinone; retenequinone; 7,8,9,10-tetrahydronaphthalenequinone; and 1,2,3,4-tetrahydrobenz(a)anthracene-7,12-dione. Other photoinitiators are described in U.S. Pat. No. 2,760,863 and include vicinal ketaldonyl alcohols, such as benzoin, pivaloin, acyloin ethers, e.g., benzoin methyl and ethyl ethers; and alpha-hydrocarbon-substituted aromatic acyloins, including alpha-methylbenzoin, alpha-allylbenzoin, and alpha-phenylbenzoin. Photoreducible dyes and reducing agents disclosed in U.S. Pat. Nos. 2,850,445; 2,875,047; and 3,097,096 as well as dyes of the phenazine, oxazine, and quinone classes; benzophenone, 2,4,5-triphenylimidazolyl dimers with hydrogen donors, and mixtures thereof as described in U.S. Pat. Nos. 3,427,161; 3,479,185; and 3,549,367 can be also used as photoinitiators.

The resist composition can further optionally include a surfactant. Illustrative surfactants include fluorinated and non-fluorinated surfactants, and are preferably non-ionic.

Exemplary fluorinated non-ionic surfactants include perfluoro C4 surfactants such as FC-4430 and FC-4432 surfactants, available from 3M Corporation; and fluorodiols such as POLYFOX™ PF-636, PF-6320, PF-656, and PF-6520 fluorosurfactants from Omnova.

A surfactant may be included in an amount of 0.01 to 5 weight percent, specifically 0.1 to 4 weight percent, more specifically 0.2 to 3 weight percent, based on the total weight of solids.

The resist composition may then be used to pattern substrates for use as semiconductors. Another embodiment is a coated substrate comprising: (a) a substrate having one or more layers to be patterned on a surface thereof; and (b) a layer of the resist composition of over the one or more layers to be patterned.

The substrate can be of a material such as a semiconductor, such as silicon or a compound semiconductor (e.g., HI-V or II-VI), glass, quartz, ceramic, copper and the like. Typically, the substrate is a semiconductor wafer, such as single crystal silicon or compound semiconductor wafer, having one or more layers and patterned features formed on a surface thereof. Optionally, the underlying base substrate material itself may be patterned, for example, when it is desired to form trenches in the base substrate material. Layers formed over the base substrate material may include, for example, one or more conductive layers such as layers of aluminum, copper, molybdenum, tantalum, titanium, tungsten, and alloys, nitrides or silicides of such metals, doped amorphous silicon or doped polysilicon, one or more dielectric layers such as layers of silicon oxide, silicon nitride, silicon oxynitride or metal oxides, semiconductor layers, such as single-crystal silicon, underlayers, antireflective layers such as a bottom antireflective layers, and combinations thereof. The layers can be formed by various techniques, for example, chemical vapor deposition (CVD) such as plasma-enhanced CVD, low-pressure CVD or epitaxial growth, physical vapor deposition (PVD) such as sputtering or evaporation, electroplating or spin-coating.

The invention further includes a method of forming an electronic device, comprising: (a) applying a layer of any of the photoresist compositions described herein on a substrate; (b) pattern-wise exposing the photoresist composition layer to activating (e.g., ultraviolet or electron beam) radiation; (c) developing the exposed photoresist composition layer to provide a resist relief image. The method can, optionally, further include (d) etching the resist relief pattern into the underlying substrate. In an embodiment, the activating radiation is ArF radiation having a wavelength of 193 nm.

Applying the photoresist composition to the substrate can be accomplished by any suitable method, including spin coating, spray coating, dip coating, and doctor blading. In some embodiments, applying the layer of photoresist composition is accomplished by spin coating the photoresist in solvent using a coating track, in which the photoresist composition is dispensed on a spinning wafer. During dispensing, the wafer can be spun at a speed of up to 4,000 rotations per minute (rpm), specifically 500 to 3,000 rpm, and more specifically 1,000 to 2,500 rpm. The coated wafer is spun to remove solvent, and baked on a hot plate to remove residual solvent and free volume from the film to make it uniformly dense.

Pattern-wise exposure is then carried out using an exposure tool such as a stepper, in which the film is irradiated through a pattern mask and thereby is exposed pattern-wise. In some embodiments, the method uses advanced exposure tools generating activating radiation at wavelengths capable of high resolution including extreme-ultraviolet (EUV) or electron-beam (e-beam) radiation. It will be appreciated that exposure using the activating radiation decomposes the PAG in the exposed areas and generates acid and decomposition by-products, and that the acid then effects a chemical change in the polymer (deblocking the acid sensitive groups to generate a base-soluble group, or alternatively, catalyzing a cross-linking reaction in the exposed areas) during the post exposure bake (PEB) step. The resolution of such exposure tools can be less than 30 nanometers.

Developing the exposed photoresist layer is then accomplished by treating the exposed layer with a suitable developer capable of selectively removing the exposed portions of the film (where the photoresist is positive tone) or removing the unexposed portions of the film (where the photoresist is crosslinkable in the exposed regions, i.e., negative tone). In some embodiments, the photoresist is positive tone based on a polymer having acid-sensitive (deprotectable) groups, and the developer is preferably a metal-ion-free tetraalkylammonium hydroxide solution, such as, for example, aqueous 0.26 Normal tetramethylammonium hydroxide. Alternatively, negative tone development (NTD) can be conducted by use of a suitable organic solvent developer. NTD results in the removal of unexposed regions of the photoresist layer, leaving behind exposed regions due to polarity reversal of those regions. Suitable NTD developers include, for example, ketones, esters, ethers, hydrocarbons, and mixtures thereof. Other suitable solvents include those used in the photoresist composition. In some embodiments, the developer is 2-heptanone or a butyl acetate such as n-butyl acetate. Whether the development is positive tone or negative tone, a pattern forms by developing.

The photoresist can, when used in one or more such a pattern-forming processes, be used to fabricate electronic and optoelectronic devices such as memory devices, processor chips (including central processing units or CPUs), graphics chips, and other such devices.

The resist composition disclosed herein is exemplified by the following non-limiting examples.

### EXAMPLE

### Example 1

This example was conducted to demonstrate the synthesis of the cyclic imide repeat unit that is used in the resist composition.

The reaction to synthesize the cyclic imide repeat unit is depicted below. The structures are numbered 1, 2 and 3 and these numbers are used to identify the product being synthesized.

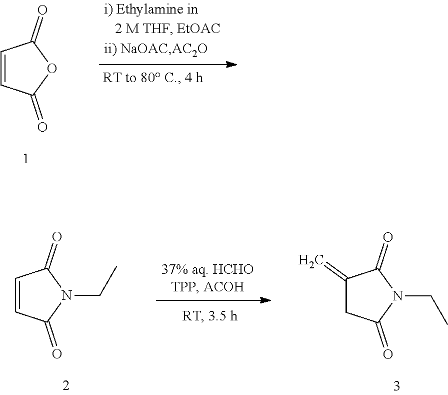

Synthesis of Compound 2: Compound-1 (450 g, 4.5918 mol) was dissolved in ethyl acetate (EtOAC) (6.75 L), then ethylamine in 2M tetrahydrofuran (THF) (2.52 L, 5.0510 mol) was added dropwise at 0° C. The reaction mixture was stirred at room temperature for 1 hour. On completion of the reaction, the reaction mixture was filtered and dried under vacuum to get the intermediate, N-substituted aminobutenoic acid. In a separate flask, a mixture of sodium acetate (NaOAC) and acetic anhydride (AC20) was heated to 80° C. N-substituted aminobutenoic acid was added to this solution at 80° C. The reaction mixture was stirred at 80° C. for 1 hour. On completion of the reaction, the reaction mixture was cooled to room temperature and diluted with ice cold water and extracted with ethyl acetate. The organic layer was dried over sodium sulfate and concentrated to get residue. Residue was purified by column using silica gel (0 to 15% ethyl acetate:Petroleum ether) to get 150 g (26%) of 2 as a yellow solid.

Synthesis of Compound 3: Compound-2 (150 g, 1.2 mol) was dissolved in acetic acid (ACOH) (480 mL), then triphenylphosphine (TPP) was added (315 g, 1.2 mol) at room temperature and the mixture stirred for 1 hour. Formalin (HCOH) (90 mL) was then added dropwise. The reaction mixture was stirred at room temperature for 2.5 hour. On completion of the reaction, the reaction mixture was diluted with water and extracted with dichloromethane. Organic layer was dried over sodium sulfate, concentrated under reduced vacuum to get residue. Residue was purified by column using silica gel (0 to 15% ethyl acetate:Petroleum ether) to produce Compound 3, 150 g (89.9%) as a pale yellow liquid.

### Example 2

This example was conducted to demonstrate the manufacturing of the resist polymer (the resist copolymer) and to compare the solubility of the resist polymer versus resist polymers that do not contain the lactam monomers and/or imide monomers. A monomer feed solution was prepared with 22.8 g ethyl lactate, 9.8 g gamma-butyrolactone (GBL), 9.56 g Compound-4, 8.92 g Compound-6, and 3.65 g Compound-3. The reference numerals for the various compounds are shown below. Separately an initiator feed solution was prepared with 8.3 g ethyl lactate, 3.5 g gamma-butyrolactone, and 1.16 g V-601. In a reactor, 9.4 g of 70/30 ethyl lactate/GBL was warmed to 80° C., and then the monomer feed solution was added dropwise at 0.20 mL/min for 240 minutes, and the initiator feed solution was added dropwise at 0.084 mL/min for 90 minutes. After 4 hours, the reaction mixture was cooled to room temperature at 1° C./min, and then the polymer precipitated by adding directly to 1 L (liter) isopropyl alcohol. The polymer was collected by filtration and dried in vacuo, affording 16.3 g of a white solid. Molecular weight was determined by GPC relative to polystyrene standard and was found to be number average molecular weight (Mₙ)=4510 Da, weight average molecular weight (MW)=8050 Daltons, PDI (polydispersity index)=1.8.

It is to be noted that all of the polymers in Table 1 were prepared according to this general synthesis protocol.

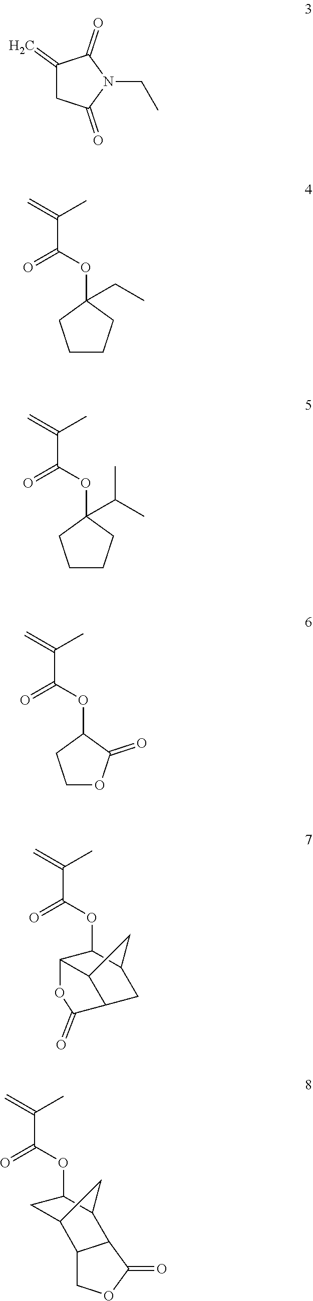

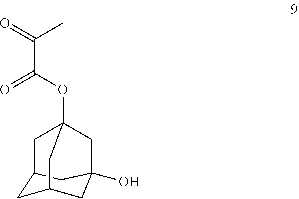 [SMILES: CC(=O)C(=O)OC12CC3CC(CC(O)(C3)C1)C2]

TABLE 1

| Polymer | Monomer 1 | Monomer 2 | Monomer 3 | Monomer 4 | Monomer 5 | Mn | Mw | PDI |
|---|---|---|---|---|---|---|---|---|
| 1 | 4 (40%) | 6 (40%) | 3 (20%) | | | 4510 | 8050 | 1.8 |
| 2 | 4 (40%) | 6 (30%) | 3 (20%) | 9 (10%) | | 5120 | 8890 | 1.7 |
| 3 | 4 (20%) | 5 (20%) | 6 (30%) | 7 (20%) | 3 (10%) | 4760 | 8010 | 1.7 |
| 4 | 4 (20%) | 5 (20%) | 6 (30%) | 3 (20%) | 9 (10%) | 5490 | 8850 | 1.6 |
| 5 | 4 (20%) | 5 (20%) | 6 (30%) | 3 (30%) | | 5780 | 10150 | 1.8 |
| 6 | 4 (20%) | 5 (20%) | 3 (30%) | 7 (20%) | 9 (10%) | 5010 | 9490 | 1.9 |
| C1 | 4 (40%) | 6 (30%) | 8 (20%) | 9 (10%) | | 5220 | 9400 | 1.8 |
| C2 | 4 (40%) | 6 (40%) | 8 (20%) | | | 4260 | 7670 | 1.8 |

where C1 and C2 in Table 1 are comparative compositions since they do not contain compound 3.

TABLE 2

| Polymer | 10% solubility in PGMEA |
|---|---|
| 1 | Y |
| 2 | Y |
| 3 | Y |
| 4 | Y |
| C1 | N |
| C2 | N |

From Table 2 it may be seen that the example polymers have good solubility in the solvent propylene glycol monomethyl ether acetate while the comparative compositions are not soluble in the solvent propylene glycol monomethyl ether acetate.

### Example 3

This example was conducted to determine the resist properties of the resist composition. The formulations R1-R2 (resist compositions) and CR1-CR2 (comparative resist compositions) were prepared with components and in amounts shown in Table 3. In Table 3, the number in bracket indicates the weight ratio of each component. The structures represented by C1, F1, P1, S and S2 are depicted below the Table 3.

TABLE 3

| Resist | | | | | |
|---|---|---|---|---|---|
| Compo- | Polymer | Polymer | | | |
| sition | 1 | 2 | PAG | Quencher | Solvent |
| R1 | 1 [2.27] | F1 [0.09] | P1 [0.53] | Q1 [0.11] | S1/S2 |
| | | | | | [33.95/63.05] |
| CR1 | C1 [2.27] | F1 [0.09] | P1 [0.53] | Q1 [0.11] | S1/S2 |
| | | | | | [33.95/63.05] |
| R2 | 2 [2.27] | F1 [0.09] | P1 [0.53] | Q1 [0.11] | S1/S2 |
| | | | | | [33.95/63.05] |
| CR2 | C2 [2.27] | F1 [0.09] | P1 [0.53] | Q1 [0.11] | S1/S2 |
| | | | | | [33.95/63.05] |

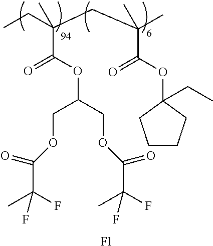

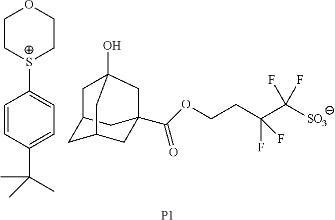

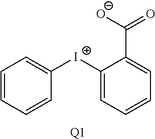

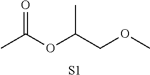

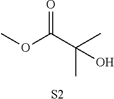

Immersion lithography was carried out with a TEL Lithius 300 mm wafer track and ASML 1900i immersion scanner at 1.3 NA (numerical aperture), 0.86/0.61 inner/outer sigma, and dipole illumination with 35Y polarization. Wafers for photolithographic testing were coated with 800 Å AR40A bottom antireflective coating (BARC) using a cure of 205° C./60 sec. Over the AR40A layer was coated 400 Å of AR104 BARC using a cure of 175° C./60 sec. Over the BARC stack was coated 900 Å of photoresist using a 90° C./60 sec soft bake. Wafers were exposed to patterns of 55 nm/110 nm pitch line/space at increasing focus and increasing dose and then post exposure baked (PEB) at 100° C./60 sec. Following PEB, wafers were developed in 0.26 N aqueous TMAH developer for 12 sec, rinsed with distilled water, and spun dry.

Metrology was carried out on a Hitachi CG4000 CD-SEM. Line width roughness (LWR) was determined by obtaining a 3-sigma value from the distribution of a total of 100 arbitrary points of line width measurements, followed by removing metrology noise using MetroLER software.

Table 4 details the Exposure latitude (EL) and line-width roughness (LWR) evaluation at 55 nm 1:1 LS (line space patterns).

TABLE 4

| Example | Resist composition | EL (%) | LWR (nm) |
|---|---|---|---|
| Ex 1 | R1 | 16.2 | 2.35 |
| Comp Ex 1 | CR1 | 13.9 | 2.40 |
| Ex 2 | R2 | 17.4 | 2.51 |
| Comp Ex 2 | CR2 | 15.6 | 2.67 |

From Table 4 it may be seen that line width roughness is reduced and the exposure latitude increased for the disclosed compositions (R1 and R2) versus the comparative compositions (CR1 and CR2).

What is claimed is:

1. A polymer comprising:
a first repeat unit and a second repeat unit, where the first repeat unit contains an acid labile group and where the second repeat unit has the structure of formula (1): 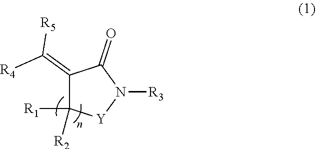
wherein R₁, R₂ and R₃ are each independently hydrogen, a halogen, a substituted or unsubstituted C₁ to C₁₂ alkyl group or C₃ to C₁₂ cycloalkyl group optionally containing an ether group, a carbonyl group, an ester group, a carbonate group, an amine group, an amide group, a urea group, a sulfate group, a sulfone group, a sulfoxide group, an N-oxide group, a sulfonate group, a sulfonamide group, or a combination thereof, a substituted or unsubstituted C₆ to C₁₄ aryl group, or C₃ to C₁₂ heteroaryl group, wherein the substitution is halogen, hydroxyl, cyano, nitro, C₁ to C₁₂ alkyl group, C₁ to C₁₂ haloalkyl group, C₁ to C₁₂ alkoxy group, C₃ to C₁₂ cycloalkyl group, amino, C₂-C₆ alkanoyl, carboxamido, a substituted or unsubstituted C₆ to C₁₄ aryl group, or C₃ to C₁₂ heteroaryl group;
wherein R₁ and R₂ together optionally form a ring;
wherein Y is chosen from carbonyl, sulfonyl, or substituted or unsubstituted methylene,
wherein Y and R₂ together optionally form a substituted or unsubstituted 4-7 member monocyclic ring or a substituted or unsubstituted 9-12 member bicyclic ring, the monocyclic and bicyclic rings optionally containing 1, 2, or 3 heteroatoms chosen from N, O, and S, wherein each ring is saturated, unsaturated, or aromatic, and wherein each ring optionally contains an ether group, a carbonyl group, an ester group, a carbonate group, an amine group, an amide group, a urea group, a sulfate group, a sulfone group, a sulfoxide group, an N-oxide group, a sulfonate group, a sulfonamide group, or a combination thereof, wherein the substitution on the ring is halogen, hydroxyl, cyano, nitro, C₁ to C₁₂ alkyl group, C₁ to C₁₂ haloalkyl group, C₁ to C₁₂ alkoxy group, C₃ to C₁₂ cycloalkyl group, amino, C₂-C₆ alkanoyl, carboxamido, a substituted or unsubstituted C₆ to C₁₄ aryl group, or C₃ to C₁₂ heteroaryl group; and wherein R₄ and R₅ are each independently hydrogen, halogen, a substituted or unsubstituted C₁ to C₃ alkyl group where the substitution is halogen; and wherein n=1-3.

2. The polymer of claim 1, where the first repeat unit has the structure of formula (4) 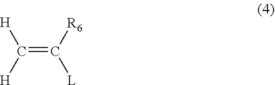
where R₆ is a hydrogen or an alkyl group having 1 to 10 carbon atoms and where L comprises a carbonyl group, a single bond, or an aromatic unit.

3. The polymer of claim 1, where the first repeat unit is a (meth)acrylate monomer or a vinyl aromatic monomer.

4. The polymer of claim 1, where first repeat unit comprises a tertiary alkyl ester.

5. The polymer of claim 1, where the acid labile group is an acetal group or a ketal group.

6. The polymer of claim 1, where the second repeat unit having the structure of formula (1) is selected from: 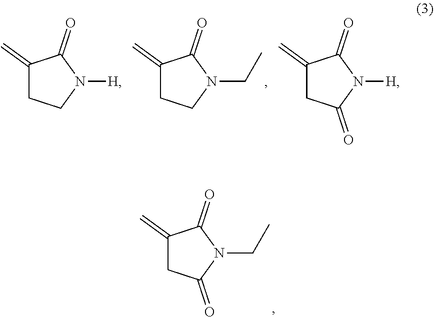
or a combination thereof.

7. The polymer of claim 1, where the second repeat unit is

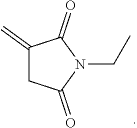

8. The polymer of claim 1, further comprising a third repeat unit that contains a lactone group and/or a sultone group.

9. A photoresist composition comprising:
a solvent;
a photoacid generator; and the polymer of claim 1.

10. A pattern formation method, comprising:
applying a layer of the photoresist composition of claim 9 over a substrate;
pattern-wise exposing the photoresist composition layer to activating radiation; and
developing the exposed photoresist composition layer to provide a resist relief image.
